(19) United States
(12) Patent Application Publication
(10) Pub. No.: US 2012/0008450 A1
(43) Pub. Date: Jan. 12, 2012

(54) FLEXIBLE MEMORY ARCHITECTURE FOR STATIC POWER REDUCTION AND METHOD OF IMPLEMENTING THE SAME IN AN INTEGRATED CIRCUIT

(75) Inventors: Mark F. Turner, Longmont, CO (US); Jeffrey S. Brown, Fort Collins, CO (US); Paul J. Dorweiler, Windsor, CO (US)

(73) Assignee: LSI Corporation, Milpitas, CA (US)

(21) Appl. No.: 12/831,439

(22) Filed: Jul. 7, 2010

(51) Int. Cl. G11C 8/00; G06F 17/50

(52) U.S. Cl. 365/230.03; 716/108; 716/118

(57) ABSTRACT

A memory for an integrated circuit, a method of designing a memory and an integrated circuit manufactured by the method. In one embodiment, the memory includes: (1) one of: (1a) at least one data input register block and at least one bit enable input register block and (1b) at least one data and bit enable merging block and at least one merged data register block, (2) one of: (2a) at least one address input register block and at least one binary to one-hot address decode block and (2b) at least one binary to one-hot address decode block and at least one one-hot address register block and (3) a memory array, at least one of the blocks having a timing selected to match at least some timing margins outside of the memory.

### TECHNICAL FIELD

This application is directed, in general, to computer memory and, more specifically, to a flexible memory architecture for static power reduction and method of implementing the same in an integrated circuit (IC).

### BACKGROUND

Modern digital complementary metal-oxide semiconductor (CMOS) ICs benefit from the use of ever-faster transistors. Unfortunately, generally speaking, the faster a transistor switches, the harder it is to turn it completely off. For this reason, fast transistors in such ICs tend to leak current even in their “off” state. This current leakage is not only the largest cause of static power consumption in today's digital logic, but is also a growing factor in total power consumption.

Compounding the problem is that some of the IC design is beyond the direct control of most IC designers. Memories (e.g., dynamic random-access memories, or DRAMs, static random-access memories, or SRAMs, including register files) are almost always generated using software automation (e.g., a silicon compiler) so designers do not have to recreate basic memory building blocks used repeatedly in one IC design after another. Unfortunately, this has caused designers to regard memories generated by means of automation as unchangeable, rigid architectures.

### SUMMARY

One aspect provides a memory for an IC. In one embodiment, the memory includes: (1) one of: (1a) at least one data input register block and at least one bit enable input register block and (1b) at least one data and bit enable merging block and at least one merged data register block, (2) one of: (2a) at least one address input register block and at least one binary to one-hot address decode block and (2b) at least one binary to one-hot address decode block and at least one one-hot address register block and (3) a memory array, at least one of the blocks having a timing selected to match at least some timing margins outside of the memory.

Another aspect includes a method of designing a memory in an IC. In one embodiment, the method includes employing software automation to: (1) determine at least some timing margins outside of the memory by employing timing reports regarding the IC, (2) determine a timing that internal logical functions of the memory should have to match the timing margins and (3) edit an original description of the memory to implement a flexible memory architecture and implement leakage power reduction with respect thereto.

Yet another aspect includes an IC manufactured by the process comprising employing software automation to: (1) determine at least some timing margins outside of the a memory of the IC by employing timing reports regarding the IC, (2) determine a timing that internal logical functions of the memory should have to match the timing margins and (3) edit an original description of the memory to implement a flexible memory architecture and implement leakage power reduction with respect thereto.

### BRIEF DESCRIPTION

Reference is now made to the following descriptions taken in conjunction with the accompanying drawings, in which:

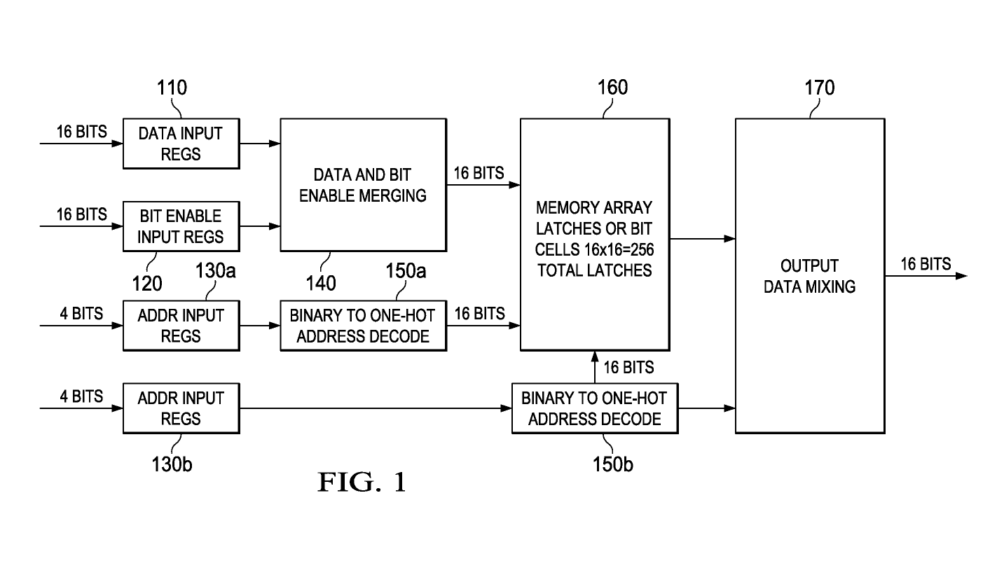

FIG. 1 is a diagram of one embodiment of a flexible memory architecture;

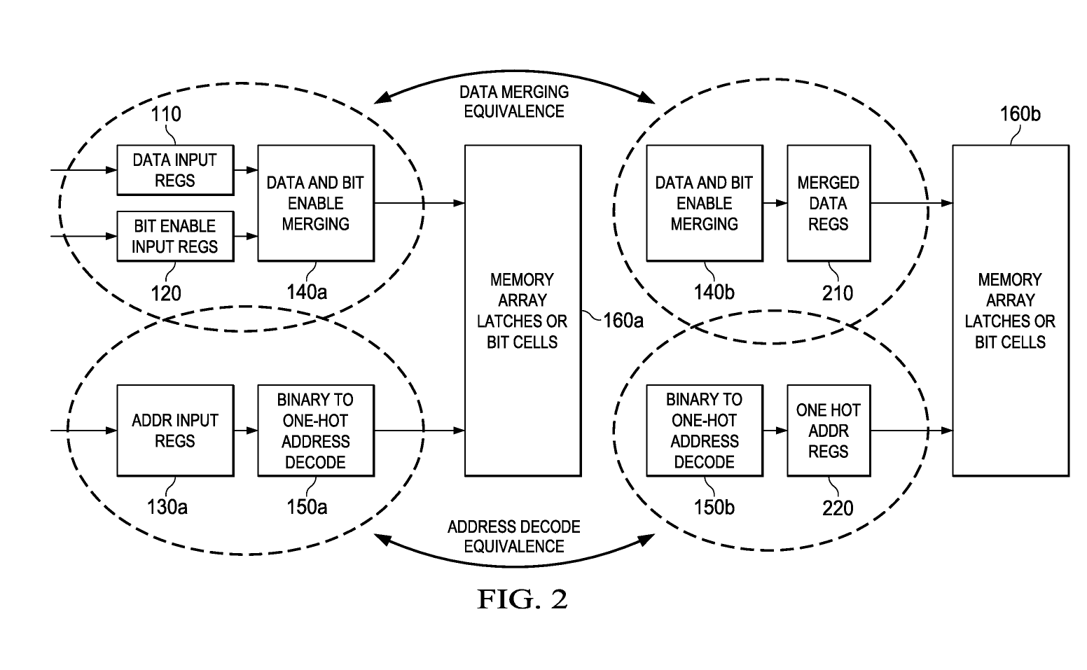

FIG. 2 is a diagram of one implementation of the flexible memory architecture of FIG. 1; and

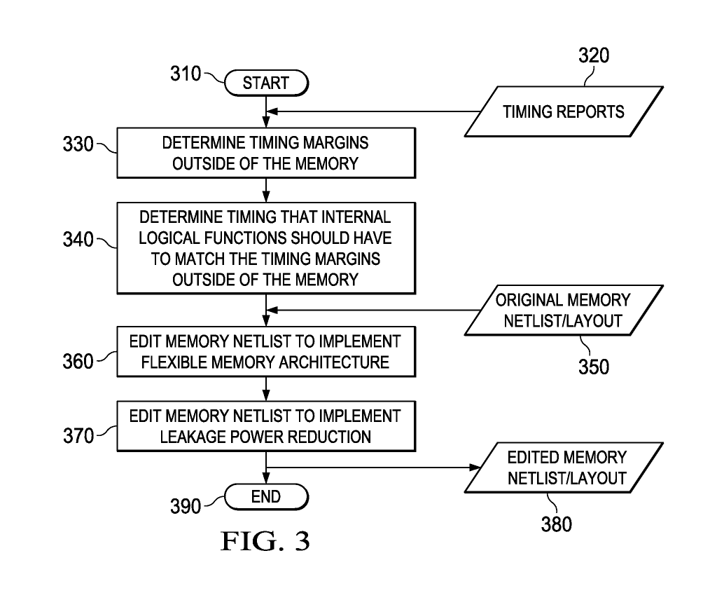

FIG. 3 is a flow diagram of one embodiment of a method of implementing a flexible memory architecture in an IC.

### DETAILED DESCRIPTION

As stated above, the widespread use of software automation has caused IC designers to regard software-generated (e.g., compiled) memories as unchangeable, rigid architectures. As a result, compiled memories of today's ICs are not designed in the context of the surrounding logical design. As a result IC designers accept whatever power consumption and leakage characteristics the compiled memories happen to have.

Those skilled in the art do understand that leakage current can be reduced by using slower transistors, such as those having longer channels or higher threshold voltages (Vt). For this reason, most commercially-available IC libraries include a selection of transistors with logic gates of various channel length and threshold voltage. This allows a designer (or any automated logic synthesis tools) to make design trade-offs in an attempt to optimize power and performance. For example, a change in channel length or threshold voltage that reduces switching speed by 10% also reduces current leakage by 50%. It is therefore possible that architectures (employing parallelism, for example) having a larger number of logic gates can not only perform functional requirements faster, but also exhibit lower current leakage. Unfortunately, while most compilers include options for trading off performance, area and power, they do not exercise these options with respect to memories because they are so often compiled. To complicate matters, while compilers include trade-off options, the options are relatively crude. They are not capable of allowing a designer to carry out fine degrees of performance, area and power optimization. For example, a compiler may allow a designer to design a circuit that is 20% slower but consumes 50% less power, but not, for example, allow the designer to design a circuit that is 10% slower but consumes 40% less power.

Those skilled in the art also understand that power may be saved by turning off idle circuitry. However, knowing what circuitry can be turned off and back on and under what conditions requires system-level knowledge and control of the design. Silicon compilers do not have access to that level of knowledge and that degree of control, and so are incapable of providing that functionality. Adding to all of this, designers rarely have the ability to affect compiler architecture, so if the various stages of a particular compiled block contain a timing margin, no way currently exists to exploit the timing margin to reduce power consumption. Currently, compilers allow designers to define the inputs and outputs of memories (e.g., register files) as “synchronous” or “asynchronous.” This is the only architectural aspect that today's compilers allow the designer to define for memory compilation, that is unless the designer wishes to design the memory from scratch.

Described herein are various embodiments of a novel, flexible memory architecture by which performance, area and power may be optimized within the context of the surrounding logic. Instead of being limited to defining inputs and outputs as being either synchronous or asynchronous, designers can specify the input registers of a “synchronous” register file to be placed before or after any logic function, such as address decoding or data-and-bit-enable encoding, to take advantage of previous-stage timing margins and allow the memory array to use long channel or higher Vt transistors for power reduction.

In general, in-context timing information regarding the logic that surrounds a memory is used to modify the architecture of the memory to reduce, and perhaps optimize, power consumption. In certain embodiments, the timing information is used to determine how the memory architecture should be implemented in a particular IC design. In certain other embodiments, the timing information is made available on all or some of the inputs or outputs of the memory, thereby determining the extent to which the surrounding logic determines how the architecture is implemented. In related embodiments, a designer manually implements the architecture. In alternative embodiments, the architecture is made available for use by a silicon compiler, enabling automatic memory compiling. In various embodiments, the architecture is implemented with a netlist-based register file that employs standard cells. However, alternative embodiments call for the architecture to be employed as part of a custom compiled memory. In various other embodiments, the architecture is employed for all types of memory, including DRAM and SRAM-based memory, and is not limited to register files.

Common memory arrays (of which a register file is a subset) consists of storage elements arranged in a two-dimensional array, the two dimensions typically being referred to as “words and bits” or “rows and columns.” The interface to the memory array is relatively compact because of the row/column access and because the address (to the words) are binary-encoded. Contrasted with the interface, the array itself is large, containing a number of storage elements equaling the words multiplied by the bits (i.e., the number of rows multiplied by the number of columns).

For example, a small, two-port 16-word by 16-bit register file has 16 data inputs, 16 data outputs, four write address line inputs, four read address line inputs, and a write enable input. Additionally, the register file has one or two clocks inputs, depending on whether or not the two ports are synchronous and synchronous with each other). The register file may also have write-masking, or bit-wise enables (“bit-enables”) over the width of the data (16 bits in this example).

FIG. 1 is a diagram of one embodiment of a flexible memory architecture for the above example. The architecture has a data input register block 110, a bit enable input register block 120, address input register blocks 130a, 130b, a data and bit enable merging block 140, binary to one-hot address decode blocks 150a, 150b, a memory array latch or bit cell block 160 and an output data multiplexing (“muxing”) block 170.

If the architecture employs conventional D flip-flops (DFFs) are employed for all its input and output (I/O) registers (and assuming an additional 16 bit-enables), the architecture will have 16*3+4*2 DFFs, totaling 56 DFFs. However, the architecture will also have 16*16 storage elements (either latches or memory bit cells), totaling 256 storage elements. In other words, the architecture of FIG. 1 contains 4.6 times as many storage elements as I/O registers. From this relationship, it becomes apparent that leakage power in the storage elements consumes more power than leakage power in the I/O registers. Therefore, leakage current reduction efforts should focus on the storage elements, and particularly those that are used the most. This is particularly true with smaller register files since they are more likely to have storage elements that resemble transparent latches, as opposed to SRAM bit cells (to reduce the read and write logic overhead of small memories).

The problem is that, in a conventional memory, the storage elements are a significant part of the overall timing delay. As a result, performance is directly related to leakage current in the memory array unless the overhead of other portions of the critical delay path can be removed. In one embodiment, this is achieved by pre-decoding the addresses before the synchronizing them with the corresponding data. In a more specific embodiment, the address pre-decoding converts a binary-encoded input into a one-of-many (or “one-hot”) bus. In the example of FIG. 1, pre-decoding converts the 4-bit binary input into a 16-bit one-hot. While this approach typically requires more registers overall, the total number of registers will still be less than the number of storage elements in the memory array 160. Because a larger set-up requirement is created on the input to the register file (the delay of the address decode is now effectively moved to the previous pipeline stage), pre-decoding can only be done if it has been determined that a sufficient timing margin exists in the previous stage of logic. This is why this architectural change must be “in context” with the design.

As FIG. 1 shows, the input data is often pre-encoded with bit-enable or write enable logic, and this pre-encoding can also be performed before the input registers in a non-conventional way if this delay path is determined to be the critical path. In this way, the encoding logic is taken totally out of the timing path of the register file and inserted into the timing path of the previous logic stage. Alternatively, the logical function may be split, and a portion of the logic may be placed on the other side of the pipeline.

FIG. 2 is a diagram of one implementation of the flexible memory architecture of FIG. 1. Data merging may be performed by a combination of the data input register block 110, the bit enable input register block 120 and the data and bit enable merging block 140a as shown on the left-hand side of FIG. 2 or the combination of the data and bit enable merging block 140b and a merged data register block 210 as shown on the right-hand side of FIG. 2. Likewise, address decoding may be performed by a combination of the address input register block 130a and the binary to one-hot address decode block 150a as shown on the left-hand side of FIG. 2 or the combination of the binary to one-hot address decode block 150b and a one-hot address register block 220 as shown on the right-hand side of FIG. 2. The memory array 160 of FIG. 1 is shown as both 160a and 160b in FIG. 2.

Typically, for a high-performance, relatively small register file and a worst-case write-through (in which the read and write addresses are identical and the written data has to propagate fully through the memory array to the outputs of the register file), the approximate delays as percentages of overall path delay have been found to be:

TABLE 1
Approximate Delay Percentages

| | | |
|---|---|---|
| 1. | Input register clock-to-Q | 20% |
| 2. | Write address decoding or input data encoding | 20% |
| 3. | Transparent latch delay | 30% |
| 4. | Output data multiplexing | 20% |
| 5. | Setup time required | 10% |
| | Overall path delay | 100% |

From Table 1, it is apparent that if write address decoding or data encoding can be moved before the input registers, about 20% of the overall path delay can be gained. Alternatively, if output data multiplexing and testing can be moved after the next register stage, an additional 20% of the overall path delay can be gained. Assuming a library contains sets of candidate transistor types that differ from one another stepwise in terms of performance (e.g., full performance, 10% reduction in performance, 20% reduction in performance, 30% reduction in performance, 40% reduction in performance, etc.), and further assuming that the transistors suffer only about 50% of the current leakage with each 20% reduction in performance, transistors having a 20% reduction in performance (by way of increased Vt or channel length) may be employed in the memory array (increasing its delay by 44%), and transistors having full performance may be employed in the input registers and line drivers. Table 2, below, reflects this substitution:

TABLE 2
Example Delay Percentages

| | | |
|---|---|---|
| 1. | Input register clock-to-Q | 24% |
| 2. | Transparent latch delay | 43.2% |
| 3. | Output data multiplexing | 20% |
| 4. | Setup time required | 10% |
| | Overall path delay | 97.2% |

Since the transparent latches are about 40% of the total power and the input registers and line drivers are about 20% of the total power, the substitution as described above reduces leakage current by about 40% (40% goes to 10% with 2 performance shifts, and 20% goes to 10% with one performance shift). In one specific example, a 500 mW current leakage can be reduced to a 300 mW current leakage just for their memory array, which may be enough to allow such memory array to be encased in a standard (non-thermally enhanced) package, saving significant cost without sacrificing power consumption.

FIG. 3 is a flow diagram of one embodiment of a method of implementing a flexible memory architecture in an IC. The method begins in a start step 310. Timing reports 320 are employed as an input to the method in a step 330 to determine timing margins outside of the memory. In a step 340, the timing that internal logical functions should have to match the timing margins outside of the memory (that were determined in the step 330) is determined. An original netlist or layout 350 describing the memory is edited in a step 360 to implement the flexible memory architecture as described herein. In a step 370, the netlist or layout describing the memory is again edited to implement leakage power reduction. The edited netlist or layout 380 describing the memory is then provided as an output of the method. The method ends in an end step 390.

Those skilled in the art to which this application relates will appreciate that other and further additions, deletions, substitutions and modifications may be made to the described embodiments.

What is claimed is:

1. A memory for an integrated circuit, comprising:
one of:
at least one data input register block and at least one bit enable input register block, and
at least one data and bit enable merging block and at least one merged data register block; one of:
at least one address input register block and at least one binary to one-hot address decode block, and
at least one binary to one-hot address decode block and at least one one-hot address register block; and
a memory array, at least one of said blocks having a timing selected to match at least some timing margins outside of said memory.

2. The memory as recited in claim 1 wherein said memory contains transistor types that differ from one another stepwise in terms of performance.

3. The method as recited in claim 2 wherein said candidate transistor types differ in terms of one of:
threshold voltage, and
channel length.

4. The memory as recited in claim 1 wherein said memory is selected from the group consisting of:
dynamic random-access memory,
static random-access memory, and
a register file.

5. A method of designing a memory in an integrated circuit, comprising:
employing software automation to:
determine at least some timing margins outside of said memory by employing timing reports regarding said integrated circuit,
determine a timing that internal logical functions of said memory should have to match said timing margins, and
edit an original description of said memory to implement a flexible memory architecture and implement leakage power reduction with respect thereto.

6. The method as recited in claim 5 wherein said description is selected from the group consisting of:
a netlist, and
a layout.

7. The method as recited in claim 5 wherein said flexible memory architecture includes at least one data input register block and at least one bit enable input register block.

8. The method as recited in claim 5 wherein said flexible memory architecture includes at least one address input register block and at least one binary to one-hot address decode block.

9. The method as recited in claim 5 wherein said flexible memory architecture includes at least one data and bit enable merging block and at least one merged data register block.

10. The method as recited in claim 5 wherein said flexible memory architecture includes at least one binary to one-hot address decode block and at least one one-hot address register block.

11. The method as recited in claim 5 wherein a library containing sets of candidate transistor types that differ from one another stepwise in terms of performance is associated with said software automation.

12. The method as recited in claim 11 wherein said candidate transistor types differ in terms of one of:
threshold voltage, and
channel length.

13. The method as recited in claim 4 wherein said memory is selected from the group consisting of:
dynamic random-access memory,
static random-access memory, and
a register file.

14. An integrated circuit manufactured by the process comprising:
employing software automation to:
determine at least some timing margins outside of said a memory of said integrated circuit by employing timing reports regarding said integrated circuit,
determine a timing that internal logical functions of said memory should have to match said timing margins, and
edit an original description of said memory to implement a flexible memory architecture and implement leakage power reduction with respect thereto.

15. The method as recited in claim 14 wherein said description is selected from the group consisting of:
a netlist, and
a layout.

16. The method as recited in claim 14 wherein said memory is selected from the group consisting of:
dynamic random-access memory,
static random-access memory, and
a register file.

17. The method as recited in claim 14 wherein said flexible memory architecture includes one of:
at least one data input register block and at least one bit enable input register block, and
at least one data and bit enable merging block and at least one merged data register block.

18. The method as recited in claim 14 wherein said flexible memory architecture includes one of:
at least one address input register block and at least one binary to one-hot address decode block, and
at least one binary to one-hot address decode block and at least one one-hot address register block.
